(19) United States
(12) Patent Application Publication
(10) Pub. No.: US 2007/0277726 A1
(43) Pub. Date: Dec. 6, 2007

(54) METHOD FOR HEAT TREATING SINGLE CRYSTAL

(76) Inventors: Tatsuya Usui, Hitachinaka-shi (JP); Naoaki Shimura, Hitachinaka-shi (JP); Yasushi Kurata, Hitachinaka-shi (JP); Kazuhisa Kurashige, Hitachinaka-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/755,787

(22) Filed: May 31, 2007

(30) Foreign Application Priority Data
Jun. 2, 2006 (JP) P2006-154653
Sep. 19, 2006 (JP) P2006-253227

(51) Int. Cl. C30B 5/00

(52) U.S. Cl. 117/7

(57) ABSTRACT

The present invention provides a method for heat treating a single crystal, comprising a step of heating a single crystal of a specific cerium-activated orthosilicate compound in an oxygen-containing atmosphere.

### BACKGROUND OF THE INVENTION

1. Field of the Invention

The present invention relates to a method for heat treating a single crystal. More particularly, the present invention relates to a method for heat treating a single crystal for use in single crystal scintillation detectors (scintillators) of radiation such as gamma radiation in the field of radiation medicine, physics, physiology, chemistry, mineralogy, and oil prospecting, e.g., for positron CT (PET) for medical diagnosis, cosmic ray observations, and exploration of underground resources.

2. Related Background Art

Scintillators of cerium-activated gadolinium orthosilicate have been used as radiation detectors, e.g., for positron CT, due to their short fluorescence decay time and a high radiation absorption coefficient. The light output of such scintillators is higher than that of BGO scintillators, but is only about 20% that of NaI (Tl) scintillators, and in this respect a significant improvement thereof is needed.

Scintillators using a single crystal of cerium-activated lutetium orthosilicate represented by Lu₂₍₁₋ₓ₎Ce₂ₓSiO₅ (see specifications of Japanese Patent No. 2,852,944 and U.S. Pat. No. 4,958,080 are generally known. Scintillators using a single crystal of a compound represented by Gd_{2(x+y)}LnₓCe_{y}SiO₅ (Ln is Lu or one of rare earth elements) are also generally known (see specifications of Japanese Published Examined Patent Application No. 7-78215 and U.S. Pat. No. 5,264,154) are also generally known. These scintillators are known to have an increased density of crystals, and also an increased light output of single crystals of cerium-activated orthosilicate compounds, and a shortened fluorescence decay time.

Further, a method for heat treating a single crystal of cerium-activated gadolinium orthosilicate with the object of improving the scintillation characteristics such as light output and energy resolution is also known (see specification of Japanese Patent No. 2,701,577). With this heat treatment method, the heat treatment is carried out in an atmosphere with a low concentration of oxygen and at a high temperature (at a temperature 50 to 550° C. lower that the melting point of the single crystal). According to the aforementioned documents, the scintillation characteristics are improved due to the reduction of tetravalent Ce ions, which hinder the scintillation emission, into trivalent ions.

### SUMMARY OF THE INVENTION

However, in the single crystals of cerium-activated orthosilicate compounds that are disclosed in the above-described documents, the background of light output easily increases. As a result, a spread of fluorescence characteristics inside a crystal ingot or between the crystal ingots, variation within a day, and variation thereof with time under natural light irradiation including ultraviolet radiation occur easily, and a stable light output characteristic is difficult to obtain.

Further, it was established that when single crystals of cerium-activated orthosilicate compounds represented by the following general formulas (1), (2), and (6), from amongst the single crystals of cerium-activated orthosilicate compounds, are grown or cooled in an atmosphere with a low concentration of oxygen, or heated at a high temperature in an atmosphere with a low concentration of oxygen after the growth, the background of light output rises and the light output decreases.
Y_{2-(x+y)}LnₓCe_{y}SiO₅ (1)

In formula (1), Ln denotes at least one element selected from a group consisting of elements belonging to rare earth elements, x is a numerical value of 0 to 1, and y is a numerical value of more than 0 and equal to or less than 0.2.
Gd₂₋₍ᵣ₊ₛ₎LuᵣCeₛSiO₅ (2)

In formula (2), Ln denotes at least one element selected from a group consisting of elements belonging to rare earth elements, z is a numerical value of more than 0 and equal to or less than 1, and w is a numerical value of more than 0 and equal to or less than 0.2.
Gd₂₋₍ᵣ₊ₛ₎LuᵣCeₛSiO₅ (6)

In formula (6), r is a numerical value of more than 0 and equal to or less than 1, and s is a numerical value of more than 0 and equal to or less than 0.2.

This tendency becomes especially significant in the case of single crystals using at least one element selected from a group consisting of Dy, Ho, Er, Tm, Yb, Lu, Y, and Sc, which are rare earth elements with an ion radius less than that of Tb, as the Ln in general formula (1) or (2).

Furthermore, the heat treatment method disclosed in Japanese Patent No. 2,701,577 demonstrates good results when carried out with respect to single crystals of Gd₂₍₁₋ₓ₎Ce₂ₓSiO₅ (cerium-activated gadolinium orthosilicate). However, when single crystals of cerium-activated orthosilicate compounds represented by general formula (1) above and single crystals of cerium-activated gadolinium orthosilicate represented by general formula (2) or (6) above are the objects of the heat treatment, the background of light output increases. Therefore, the heat treatment was found to produce a negative effect of decreasing the light output. This tendency becomes especially significant in the case of single crystals using at least one element selected from a group consisting of Dy, Ho, Er, Tm, Yb, Lu, Y, and Sc, which are rare earth elements with an ion radius less than that of Th, as the Ln in general formula (1) or (2) above.

Further, a method is known by which a single crystal of a specific cerium-activated orthosilicate compound is grown or cooled in an atmosphere comprising oxygen (for example, an atmosphere with an oxygen concentration of 0.2 vol. % or more) and then heat treatment of the single crystal is performed at a high temperature in the atmosphere comprising oxygen. However, this method is found to cause the coloration of crystals and decrease in light output due to absorption of the fluorescence. This tendency becomes especially significant in the case of single crystals with a composition ratio of Ln to Y or Gd of 50% or less, as in the cerium-activated orthosilicate compounds represented by general formulas (1), (2), and (6) above.

The present invention was created with the foregoing in view and it is an object thereof to provide a method for heat treating a single crystal that can improve the light output characteristic and energy resolution characteristic with respect to the conventional ones even in the case of cerium-activated orthosilicate compounds represented by general formulas (1), (2), and (6) above, in particular single crystals using at least one element selected from a group consisting of Dy, Ho, Er, Tm, Yb, Lu, Y, and Sc, which are rare earth elements with an ion radius less than that of Tb, as the Ln in general formula (1) or (2).

The present invention provides a method for heat treating a single crystal, comprising a step of heating a single crystal of a cerium-activated orthosilicate compound, represented by general formula (1) or (2) below, that comprises 0.00005 to 0.1 wt.% of an element of Group 2 of the periodic table at a temperature T₁ (units: ° C.) satisfying a condition represented by formula (3) below in an atmosphere with a low concentration of oxygen:
Y_{2-(x+y})LnₓCe_{y}SiO₅ (1)
here, in formula (1), Ln denotes at least one element selected from a group consisting of elements belonging to rare earth elements including Y and Sc, x is a numerical value of 0 to 1, and y is a numerical value of more than 0 and equal to or less than 0.2,
Gd_{2-(z+w)}Ln_{z}Ce_{w}SiO₅ (2)
here, in formula (2), Ln denotes at least one element selected from a group consisting of elements belonging to rare earth elements including Y and Sc, z is a numerical value of more than 0 and equal to or less than 1, and w is a numerical value of more than 0 and equal to or less than 0.2,
800≦T₁<(Tₘ₁−550) (3)
here, in formula (3), Tₘ₁ (units: ° C.) denotes a melting point of the single crystal.

Because the method in accordance with the present invention comprises a heat treatment step in which heat treatment is carried out at a temperature that is somewhat lower than the melting point of a single crystal in an atmosphere with a low concentration of oxygen, the cerium present in the single crystal represented by general formula (1) or (2) above can be made to be present with good stability as trivalent cerium ions serving as centers of light emission. As a result, coloration of the single crystal can be suppressed and the generation of oxygen vacancies can be prevented. In addition, because the element of Group 2 of the periodic table is contained in an amount of 0.00005 to 0.1 wt. %, the light output can be increased. As a result, the light output and energy resolution can be increased and the increase in the background of light output and a spread in the light output can be suppressed.

The present invention also provides a method for heat treating a single crystal, comprising a step of heating a single crystal of a cerium-activated orthosilicate compound, represented by general formula (4) below, that comprises 0.00005 to 0.1 wt. % of an element of Group 2 of the periodic table at a temperature T₂ (units: ° C.) satisfying a condition represented by formula (5) below in an atmosphere with a low concentration of oxygen:
Gd_{2-(p+q)}LnₚCe_{q}SiO₅ (4)
here, in formula (4), Ln denotes at least one element selected from a group consisting of Dy, Ho, Er, Tm, Yb, Lu, Y, and Sc, which are rare earth elements with an ion radius less than that of Th, p is a numerical value of more than 0 and equal to or less than 1, and q is a numerical value of more than 0 and equal to or less than 0.2,
800≦T₂<(Tₘ₂−550) (5)
here, in formula (5), Tₘ₂ (units: ° C.) denotes a melting point of the single crystal.

The present invention also provides a method for heat treating a single crystal, comprising a step of heating a single crystal of a cerium-activated orthosilicate compound, represented by general formula (6) below, that comprises 0.00005 to 0.1 wt. % of an element of Group 2 of the periodic table at a temperature T₃ (units: ° C.) satisfying a condition represented by formula (7) below in an atmosphere with a low concentration of oxygen:
Gd₂₋₍ᵣ₊ₛ₎LuᵣCeₛSiO₅ (6)
here, in formula (6), r is a numerical value of more than 0 and equal to or less than 1, and s is a numerical value of more than 0 and equal to or less than 0.2,
800≦T₃<(Tₘ₃−550) (7)
here, in formula (7), Tₘ₃ (units: ° C.) denotes a melting point of the single crystal.

The present invention provides the method for heat treating a single crystal, wherein a concentration of oxygen in the atmosphere with a low concentration of oxygen is less than 0.2 vol. % and the balance is an inactive gas.

The present invention provides the method for heat treating a single crystal, wherein a concentration of hydrogen in the atmosphere with a low concentration of oxygen is 0.5 vol. % or more.

The present invention provides the method for heat treating a single crystal, wherein the element of Group 2 of the periodic table is at least one element selected from a group consisting of Be, Mg, Ca, and Sr.

The present invention provides the method for heat treating a single crystal, wherein the single crystal is a single crystal that is grown or cooled in an atmosphere comprising oxygen or a single crystal that is heated in an atmosphere comprising oxygen before the heat treatment step.

The present invention can provide a method for heat treating a single crystal that can improve the light output characteristic and energy resolution characteristic with respect to the conventional ones even in the case of cerium-activated orthosilicate compounds represented by general formulas (1), (2), and (6) above, in particular single crystals using at least one element selected from a group consisting of Dy, Ho, Er, Tm, Yb, Lu, Y, and Sc, which are rare earth elements with an ion radius less than that of Th, as the Ln in general formula (1) or (2), this method being also effective in suppressing the occurrence of crystal coloration and preventing the decrease in the light output caused by coloration.

### BRIEF DESCRIPTION OF THE DRAWINGS

FIG. 1 is a schematic cross-sectional view illustrating an example of the basic configuration of the growing device for growing a single crystal.

### DESCRIPTION OF THE PREFERRED EMBODIMENTS

The preferred embodiments of the present invention will be described below in greater detail, but they place no limitation on the scope of the present invention.

If single crystals of cerium-activated rare earth orthosilicate compounds are grown or heated in an atmosphere comprising oxygen, then trivalent cerium ions that are emission centers are changed into tetravalent ions. This change causes decrease in the number of emission centers and increase in fluorescence absorption caused by coloration of the crystals. As a result, the light output is known to decreases. This phenomenon becomes more pronounced if the oxygen concentration in the atmosphere increases or the heating temperature rises.

In single crystals of specific cerium-activated rare earth orthosilicate compounds, cerium ions are present in a trivalent state if the single crystals are grown or cooled in an atmosphere with a low concentration of oxygen or heated in an atmosphere with a low concentration of oxygen. As a result, the coloration of crystals is sufficiently suppressed and the absorption of fluorescence caused by coloration is also sufficiently suppressed. This is apparently why a high light output can be obtained. Further, even if the light output of single crystals of cerium-activated rare earth orthosilicate compounds is decreased due to growing or cooling in an atmosphere comprising oxygen or heating in an atmosphere comprising oxygen, subsequent heat treatment in an atmosphere with a low concentration of oxygen returns tetravalent cerium ions to a trivalent state, thereby causing the increase in the number of emission centers and decrease in crystal coloration. This is known to increase the light output due to the increase in transmissivity of the single crystals. This phenomenon becomes more pronounced if the oxygen concentration in the atmosphere is low, and also if the concentration of a reducing gas such hydrogen in the atmosphere is high and the heating temperature is high.

The aforementioned growth of crystals in an atmosphere with a low concentration of oxygen and heat treatment at a high temperature were actually confirmed to provide for good fluorescence characteristics and to improve the fluorescence characteristics in single crystals of Gd₂₍₁₋ₓ₎Ce₂ₓSiO₅ (cerium-activated gadolinium orthosilicate) and the like. For example, a method comprising a step of heat treating at a high temperature (a temperature 50 to 550° C. lower than the melting point of the single crystals) in an atmosphere with a low concentration of oxygen is disclosed in Japanese Patent No. 2,701,577 as a method for heat treating a single crystal of cerium-activated gadolinium orthosilicate.

However, in the case of single crystals of cerium-activated orthosilicate compound represented by general formula (1) above and single crystals of cerium-activated gadolinium orthosilicate represented by general formula (2) or (6) above, in particular in the case of single crystals using at least one element selected from a group consisting of Dy, Ho, Er, Tm, Yb, Lu, Y, and Sc, which have an ion radius less than that of Th, as the Ln in general formula (1) or (2) above, the aforementioned growth or cooling of the single crystals in an atmosphere with a low concentration of oxygen or heat treatment in an atmosphere with a low concentration of oxygen was found to produce a negative effect by increasing the background of light output and increase the spread in fluorescent output. This effect becomes even more significant if the concentration of oxygen in the atmosphere is low, the concentration of a reducing gas such as hydrogen in the atmosphere is high, and the heating temperature is high.

One of the reasons is that when the single crystals are grown or heat treated in an atmosphere with a low concentration of oxygen, oxygen vacancies apparently appear inside the crystal lattice. Voids created by oxygen vacancies result in the formation of energy trap levels, the background of light output increases owing to thermal excitation from this level, and the spread of light output also increases.

Voids induced by oxygen vacancies tend to appear easily in crystal compositions in cerium-activated orthosilicate compounds in which the crystal structure easily becomes a C2/c structure. In single crystals of cerium-activated orthosilicate compound represented by general formula (1) above and single crystals of cerium-activated gadolinium orthosilicate represented by general formula (2) or (6) above, if at least one element selected from a group consisting of La, Pr, Nd, Pm, Sm, Eu, Ga, and Th, which are elements having an ion radius larger than that of Dy, is used as the Ln in the formulas, the crystal structure easily becomes a P2₁/c structure. On the other hand, if at least one element selected from a group consisting of Dy, Ho, Er, Tm, Yb, Lu, Y, and Sc, which have an ion radius less than that of Th, is used as the Ln in the formulas, the crystal structure easily becomes a C2/c structure. The aforementioned increase in the background of light output and spread in light output easily occur in the crystals in which the crystal structure easily becomes a C2/c structure. This is apparently because the aforementioned oxygen vacancies are easily generated when the difference between the ion radius of Ce that is an activator and the ion radius of the elements constituting the orthosilicate compound becomes large.

In the case of single crystals of cerium-activated gadolinium orthosilicate compound represented by general formula (4), the oxygen vacancies tend to be generated easier as the content ratio of Ln with a small ion radius increases. In the single crystals of cerium-activated orthosilicate compounds in which oxygen vacancies are generated easily due to the aforementioned crystal composition, the oxygen vacancies apparently appear easily even when heating is conducted in a neutral atmosphere or an atmosphere with a very low concentration of oxygen or even when heating is conducted at a lower temperature.

Further, in the Lu₂₍₁₋ₓ₎Ce₂ₓSiO₅ (cerium-activated lutetium orthosilicate), which has a C2/c crystal structure, the difference in ion radius with Ce ion is also large and, therefore, the oxygen vacancies are generated easily.

In the above-described single crystals of cerium-activated orthosilicate compounds, if the difference in the ion radius between Ce and the constituent rare earth element increases, when crystal growth is performed by a Czochralski method, the segregation coefficient of Ce from the crystal melt into the crystal is greatly decreased. This is apparently why a spread in Ce concentration easily occurs in the crystal ingot and this spread can become a cause for the spread in the background or light output of the crystal.

As for the concentration of Ce in the single crystals of cerium-activated orthosilicate compounds obtained by the heat treatment method in accordance with the present invention, the numerical values of y, w, q, and s in general formulas (1), (2), (4), and (6) above are more than 0 and not more than 0.2. Furthermore, it is preferred that these numerical values be 0.0001 to 0.02, even more preferably 0.0005 to 0.005. When the numerical values are zero, Ce that is an activator is not present. Therefore, the emission levels are not formed and no fluorescence can be obtained. On the other hand, when the numerical values exceed 0.2, the amount of Ce incorporated into the crystals reaches saturation and the effect proportional to the amount added cannot be obtained. Furthermore, voids and defects caused by segregation of Ce occur and the fluorescence characteristics tend to degrade.

As for the concentration of rare earth element Ln constituting the single crystal, the numerical value of x in general formula (1) above is 0 to 1. Further, this numerical value is preferably 0.2 to 0.8, even more preferably 0.4 to 0.6. Further, z, p, and r in general formulas (2), (4), and (6) have numerical values above 0 and equal to or less than 1. Further, these numerical values are preferably 0.2 to 0.8, even more preferably 0.4 to 0.6. In general formulas (1) and (2) above, the rare earth element Ln is preferably at least one element selected from a group consisting of Dy, Ho, Er, Tm, Yb, Lu, Y, and Sc, which have an ion radius less than that of Th. Among them, Lu is especially preferred. If x, z, p, and r in general formulas (1), (2), (4), and (6) above are more than 1, a structure is obtained in which voids induced by oxygen vacancies are easily produced. Therefore, the efficiency of suppressing the appearance of voids induced by oxygen vacancies by conducting heat treatment in an atmosphere with a low concentration of oxygen is decreased. Further, when z, p, and r in general formulas (2), (4), and (6) above are zero, the composition becomes Gd₂₍₁₋ₓ₎Ce₂ₓSiO₅ (cerium-activated gadolinium orthosilicate). Therefore, problems described in the prior art section are associated with the light output.

Further, the concentration of the element of Group 2 of the periodic table that is contained in the single crystal of a cerium-activated orthosilicate compound is 0.00005 to 0.1 wt. % based on the entire weight of the single crystal. This concentration is preferably 0.0001 to 0.05 wt. %, even more preferably 0.005 to 0.03 wt. %. When this concentration is less than 0.00005 wt. %, the effect of increasing the light output is difficult to obtain. On the other hand, when the concentration exceeds 0.1 wt. %, the number of lattice voids or crystal strains increases and cracks sometimes appear during crystal growth. In addition, the grown crystal sometimes becomes a polycrystal. Furthermore, non-emissive levels are formed due to lattice voids, and fluorescence power tends to be reduced.

The element of Group 2 of the periodic table is apparently present in the crystal lattice sites of rare earth elements such as Lu, Y, Gd or in the interstitial locations of the single crystal of cerium-activated orthosilicate compound. In particular, if a crystal lattice site of Si or a rare earth element such as Lu, Y, Gd is substituted, an element having an ion radius that is close to an ion radius of the elements constituting the base crystal (Si: 40 pm, Lu: 98 pm, Y: 102 pm, Gd: 105 pm, where 1 pm=0.01 Å) is easier to replace. If the replacement is performed with such a substituent element with a close ion radius, the appearance of lattice voids or crystal strains is prevented and a significant improvement of the light output is obtained.

In the elements of Group 2 of the periodic table, the ion radius increases in the order as follows: Be (ion radius: 35 pm), Mg (ion radius: 72 pm), Ca (ion radius: 112 pm), Sr (ion radius: 125 pm), Ba (ion radius: 142 pm), Ra (ion radius: 148 pm). Among these elements, Be, Mg, Ca, Sr demonstrate some effect by being close in ion radius to the elements in the base crystal, Mg, Ca demonstrate a significant effect, and Ca that is the closest in ion radius to Lu and Ga demonstrates the highest effect.

The process for heat treating a single crystal in accordance with the present invention will be described below.

The inventors have discovered that the spread of light output caused by the above-described appearance of oxygen vacancies can be decreased by performing a heat treatment of a single crystal at a temperature that is somewhat lower than the melting point of the crystal, even in an atmosphere with a low concentration of oxygen. Thus, the inventors have discovered that tetravalent Ce ions can be changed to trivalent Ce ions and light output can be increased, while preventing the generation of oxygen vacancies, by heating the above-described single crystal in an atmosphere with a low concentration of oxygen at a temperature T (units: ° C.) satisfying the condition represented by formula (8) below. Further, it was also discovered that when a specific element is contained or added in advance, the reduction reaction of tetravalent Ce ions into trivalent ions can be enhanced, coloration of the crystal can be inhibited, and light output can be further increased.
800<T<(Tₘ−550) (8)
here, in formula (8), Tₘ (units: ° C.) denotes a melting point of the single crystal.

The temperature T is more preferably 1000 to 1500° C., even more preferably 1200 to 1400° C. If the temperature T is less than 800° C., the effect of the present invention cannot be sufficiently demonstrated, and when the temperature is equal to or higher than (Tₘ−550)° C., oxygen vacancies can be easily generated.

An atmosphere with an oxygen concentration of 0.2 vol. % or less, the balance being an inactive gas, is preferred as the atmosphere with a low concentration of oxygen in the heat treatment process. The concentration of oxygen is preferably 0.1 vol. % or less, more preferably 300 vol.ppm or less. If the concentration of oxygen is 0.2 vol. % or more, tetravalent Ce ions are difficult to convert into trivalent ions and the effect of the present invention cannot be sufficiently demonstrated. Further, generally known gases such as He, Ar, and N₂ can be used as the inactive gas. It is preferred that the concentration of hydrogen gas as a reducing gas in the atmosphere be 0.5 vol. % or more. In this case, the effect of the present invention is enhanced, and if the concentration of hydrogen gas is 5 vol. % or more, an especially significant effect of the present invention can be demonstrated.

The suitable time required for the heat treatment (referred to hereinbelow as “treatment time”) is 1 to 50 h in the case of single crystals with the dimensions of about 4 mm×6 mm×20 mm. If the treatment time is less than 1 h, the sufficient effect of the present invention tends to be difficult to obtain. If the treatment time is more than 50 h, the effect of the present invention is difficult to increase. Therefore, the efficiency is poor and the cost efficiency is low. The effect of the present invention is apparently based on the action produced by diffusion of oxygen element in the crystal lattice as described hereinabove. Therefore, the time required to obtain a uniform effect in the entire crystal block depends of the crystal size. The larger is the crystal size the longer treatment time is required. Therefore, the upper limit for the treatment time cannot be set. The heat treatment time and temperature T of single crystals of the above-described cerium-activated rare earth orthosilicate compounds are sometimes necessary to adjust. For example, when the temperature T is close to a boundary region of the temperature at which the oxygen vacancies are generated and the temperature during the change from tetravalent cerium ions to trivalent ions, the adjustment of the treatment time can be necessary. This is because if the treatment time becomes too long with respect to the size of single crystal, then the heat treatment effect decreases and the light output, conversely, degrades even within the interval of 50 h.

As for the timing suitable for the heat treatment in accordance with the present invention, if the heat treatment is conducted after the grown crystal has been cut to the minimal predetermined size, then the effect of the present invention can be easily obtained within a short time. Therefore, such a timing is preferred. However, the heat treatment can be applied even in an ingot state, that is, after the crystal ingot has been obtained, provided that the crystal size is comparatively small. Further, the heat treatment may be also carried out in an inline mode in a growth furnace after the cooling process or with a certain superposition thereon after the crystal growth process performed by a Czochralski method or the like. Further, when a crystal is grown by a Czochralski method or the like, the heat treatment can be also applied before the separation of the crystal from the melt.

Further, with the method for heat treating a single crystal of a cerium-activated orthosilicate compound in accordance with the present invention, the effect is further increased when the method is applied to single crystals in which the ratio of tetravalent cerium ions is increased due to growing or cooling in an atmosphere comprising oxygen. The effect is also further increased when the method is applied to single crystals in which the ratio of tetravalent cerium ions is increased due to heating in an atmosphere comprising oxygen prior to the heat treatment. When the concentration of cerium in the crystal compositions represented by general formulas (1), (2), (4), and (6) above is high, the concentration of tetravalent cerium ions easily increases. Therefore, the effect of the present invention further increases.

The growth of crystals such as single crystals that is carried out prior to the above-described heat treatment may be performed by a usual method. For example, a method for growing a single crystal may comprise a melting step for obtaining a molten liquid in which the raw materials are converted to a molten state by a melting method and a cooling and solidification step for obtaining a single crystal ingot by cooling and solidifying the molten liquid.

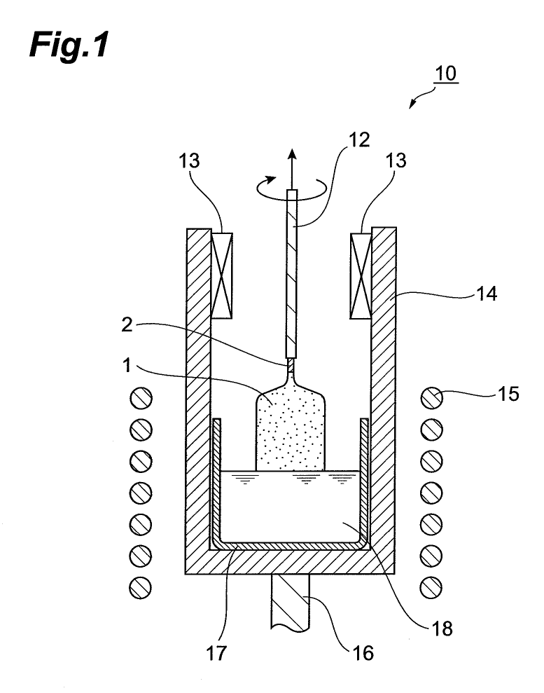

The melting method in the aforementioned melting step may be a Czochralski method. In this case, the operations in the melting step and the cooling and solidification step are preferably carried out by using a pulling device 10 having a structure shown in FIG. 1.

FIG. 1 is a schematic cross-sectional view illustrating an example of a basic configuration of a growth device for growing the single crystal in accordance with the present invention. The pulling device 10 shown in FIG. 1 has a high-frequency induction heating furnace (two-zone heating growth furnace) 14. The high-frequency induction heating furnace 14 serves to perform continuously the operations in the above-described melting step and cooling and solidification step.

The high-frequency induction heating furnace 14 is an open-end container with a fire-resistant cylindrical side wall, and the shape of the open-end container itself is identical to that used for the conventional growth of single crystals by a Czochralski method. A high-frequency induction coil 15 is wound about the side surface in the bottom section of the high-frequency induction heating furnace 14. A crucible 17 (for example, a crucible made from Ir) is disposed on the bottom surface inside the high-frequency induction heating furnace 14. The crucible 17 also serves as a high-frequency induction heater. Further, if raw materials for the single crystal are charged into the crucible 17 and a high-frequency current is induced in the high-frequency induction coil 15, the crucible 17 is heated and a molten liquid 18 (melt) composed of the constituent materials of the single crystal is obtained.

Further, a heater 13 (resistance heater) is disposed on the inner wall surface in the upper section that is not in contact with the molted liquid 18 of the high-frequency induction heating furnace 14. The heating output of the heater can be controlled independently from the high-frequency induction coil 15.

Further, an opening (not shown in the figure) passing from the inside of the high-frequency induction heating furnace 14 to the outside is provided in the center of the bottom section of the high-frequency induction heating furnace 14. A crucible support rod 16 is inserted from the outside of the high-frequency induction heating furnace 14 through the opening, and the distal end of the crucible support rod 16 is connected to the bottom section of the crucible 17. By rotating the crucible support rod 16, the crucible 17 can be rotated inside the high-frequency induction heating furnace 14. The space between the opening and the crucible support rod 16 is sealed with a packing or the like.

A more specific method for manufacturing a single crystal by using the pulling device 10 will be described above.

First in the melting step, the raw materials for a single crystal are charged into the crucible 17 and a high-frequency current is induced in the high-frequency induction coil 15, whereby the molten liquid 18 (melt) composed of the constituent materials of the single crystal is obtained. Examples of suitable raw materials for the single crystal include individual oxides and/or composite oxides of the metal elements that will constitute the single crystal. Examples of preferred commercial materials include raw materials with a high degree of purity that are manufactured by Shin-Etsu Chemical Co., Ltd., Stanford Material Co., and Tama Chemical Co., Ltd.

A cylindrical rod-like single crystal ingot 1 is then obtained by cooling and solidifying the molten liquid in the cooling and solidification step. More specifically, the operations are carried out by dividing the process into two below-described steps: a crystal growth step and a cooling step.

First, in the crystal growth step, a pulling rod 12 having a seed crystal 2 fixed to the lower distal end thereof is charged into the molten liquid 18 from above the high-frequency induction heating furnace 14. Then, the single crystal ingot 1 is formed, while the pulling rod 12 is pulled up. At this time, in the crystal growth process, the heating output of the heater 13 is adjusted and the single crystal ingot 1 that is pulled up from the molten liquid 18 is grown until the cross-sectional diameter thereof assumes a predetermined value.

Then, in the cooling step, the heating output of the heater is adjusted and the grown single crystal ingot (not shown in the figures) that is obtained after the crystal growth step is cooled. If necessary, the ingot is cut to the predetermined size to perform the heat treatment.

The present invention relates to a method for heat treating a single crystal that improves the scintillator characteristics of the above-described cerium-activated orthosilicate compounds, such as light output and energy resolution. The valence state of cerium ions in the single crystals of cerium-activated orthosilicate compounds greatly affects the light output. A change from a state of trivalent cerium ions, which are the emission centers, to a state of tetravalent cerium ions, which are non-emission centers and induce coloration and fluorescence absorption, appears due to heating in an atmosphere comprising oxygen (for example, atmosphere with an oxygen concentration of 1 vol. % or more). Conversely, heating the single crystal in an atmosphere with a low concentration of oxygen (for example, an atmosphere with a concentration of oxygen of less than 0.2 vol. %) reversibly returns the cerium ions to a trivalent state. Further, oxygen vacancies appearing in the single crystals of the cerium-activated orthosilicate compound also greatly affect the background intensity of light output. These oxygen vacancies increase the spread of fluorescence inside the crystal ingot, between the ingots, between different points in time, and such as caused by illumination with natural light comprising ultraviolet radiation. These oxygen vacancies are apparently caused by crystal growth and/or cooling in an atmosphere with a low concentration of oxygen and at a high temperature comparatively close to the melting point of the crystals, or by the heat treatment.

It was found that because the single crystal comprises the element of Group 2 of the periodic table that is present as a stable oxide in the crystal even in an atmosphere with a low concentration of oxygen and a high temperature close to the growth conditions of the single crystal, the generation of oxygen vacancies caused by heating at a high temperature in an atmosphere with a low concentration of oxygen is inhibited and, at the same time, the transition from a tetravalent state of cerium ions to a trivalent state is greatly enhanced, whereby the coloration of crystals is prevented and the light output is increased. This finding led to the creation of the present invention.

As for the valence change of cerium ion, from the standpoint of charge compensation inside a single crystal, the presence of an element of Group 2 of the periodic table apparently acts to inhibit the transition of cerium ions from a tetravalent state to a trivalent state. However, based on the discovery of the above-described unexpected action caused by the presence of an element of Group 2 of the periodic table, the present invention provides a method by which scintillator characteristics are more effectively increased because two actions relating to the valence change of cerium ions and the generation of oxygen vacancies, which are difficult to attain at the same time, can be attained by controlling the atmosphere and heating temperature (temperature T) in the heat treatment step. However, the effect of the present invention is not limited to that based on the above-described action.

In accordance with the present invention, the light output characteristic and energy resolution characteristic can be sufficiently improved even in the case of single crystals of cerium-activated orthosilicate compounds represented by general formulas (1), (2), or (6) above, in particular single crystals using at least one element selected from a group consisting of Dy, Ho, Er, Tm, Yb, Lu, Y, and Sc, which have an ion radius less than that of Th, as the Ln in general formulas (1) or (2). Further, a single crystal can be obtained that has no decrease of light output caused by coloration of the crystal, has an extremely small spread of fluorescence inside the crystal ingot, between the ingots, during the day, and such as caused by illumination with natural light comprising ultraviolet radiation, and can achieve a high light output with good stability. Further, the present invention can provide a method for heat treating a single crystal that is effective for eliminating the coloration of single crystals that easily occurs due to the increase in Ce concentration inside the crystal resulting from the increase in Ce segregation coefficient and for preventing the decrease in fluorescent output caused by the coloration in the case of single crystals in which the content ratio of Ln to Y or Gd is 50% or less.

### EXAMPLES

The present invention will be explained below in greater detail based on examples thereof, but the present invention is not limited to these examples.

### Example 1

A single crystal was produced based on the well-known Czochralski method. First, gadolinium oxide (Gd₂O₃, purity 99.99 wt. %, manufactured by Shin-Etsu Chemical Co., Ltd.), lutetium oxide (Lu₂O₃, purity 99.99 wt. %, manufactured by Stanford Material Co., Ltd.), silicon dioxide (SiO₂, purity 99.9999 wt. %, manufactured by Tama Chemical Co., Ltd.), cerium oxide (CeO₂, purity 99.99 wt. %, manufactured by Shin-Etsu Chemical Co., Ltd.) were mixed to obtain a predetermined stoichiometric composition, and a mixture, 5400 g, was fed as a raw material for a single crystal Gd₂₋₍ᵣ₊ₛ₎LuᵣCeₛSiO₅ (r=0.4, s=0.02) into an Ir crucible with a diameter of 110 mm, a height of 110 mm, and a thickness of 3 mm. Then, calcium carbonate (CaCO₃, purity 99.99 wt. %) was fed in an amount of 1.0068 g (equivalent to 0.0186 wt. % as a Ca element) as an additional element into the crucible. Heating and melting were then carried out to a melting point (about 1980° C.) in a high-frequency induction heating furnace and a molten liquid was obtained. The melting point was measured with an electronic optical pyrometer (manufactured by Chino KK, Pyrostar MODEL UR-U, product name).

Seeding was then performed by inserting a distal end of a pulling rod having a seed crystal fixed to the distal end into the molted liquid. A single crystal ingot was then pulled up at a pulling rate of 1.5 mm/h and a neck portion was formed. The cone portion was then pulled, and the pulling of the straight cylindrical body at a pulling rate of 1 mm/h was started from the point in time in which the diameter became 60 mm. After the straight cylindrical body has been grown, the single crystal ingot was separated from the melt and cooling was started. When the crystal was grown, N₂ gas at a flow rate of 4 L/min and O₂ gas at a flow rate of 2 mL/min were continuously blown into the growth furnace.

Upon completion of cooling, the single crystal obtained was removed. The obtained single crystal ingot had a crystal weight of about 3500 g, a cone portion length of about 40 mm, and a straight body length of about 170 mm.

A plurality of crystal samples in the form of rectangular parallelepipeds of 4 mm×6 mm×20 mm were cut out from the obtained single crystal ingot.

Two crystal samples were sampled at random from a plurality of crystal samples and placed into an Ir crucible. Then, in the heat treatment step, the Ir crucible was heated to a temperature of 1200° C. within about 3 h in an atmosphere with a low concentration of oxygen (oxygen concentration: 100 vol. ppm or less), the crucible was maintained at this temperature for 6 h, and then cooled to room temperature within about 10 h. The oxygen concentration was measured with a zirconia sensor (manufactured by Token KK, ECOAZ-CG O2 ANALYZER, trade name), and the nitrogen atmosphere was maintained inside the furnace used for heating the Ir crucible by blowing N₂ gas at a flow rate of 4 L/min.

The crystal samples before and after the heat treatment step were chemically etched using phosphoric acid, and the entire surface of the crystal samples was mirror finished. From among the six planes of the crystal samples in the form of rectangular parallelepipeds of 4 mm×6 mm×20 mm, five planes were covered with a polytetrafluoroethylene (PTFE) tape as a reflecting material, and one plane with a size of 4 mm×6 mm (referred to hereinbelow as “radiation incidence plane”) was left uncovered. The radiation incidence plane, which was not covered with the PTFE tape, of each obtained sample was fixed using an optical grease to a photomer plane (photoelectric conversion plane) of a photoelectronic multiplier (R878, manufactured by Hamamatsu Photonics Co., Ltd.). Each sample was then irradiated with gamma radiation of 611 KeV using ¹³⁷Cs and the energy spectrum of each sample was measured. The light output and energy resolution of each sample were evaluated. The energy spectrum was measured with MCA (manufactured by PGT Co., Ltd., trade name “Quantum MCA4000”) by applying a voltage of 1.45 kV to the photoelectronic multiplier and amplifying a signal from the dynode with a preamplifier (manufactured by ORTEC Co., Ltd., trade name “113”) and a waveform shaping amplifier (manufactured by ORTEC Co., Ltd., product name “570”). The measurement results are shown in Table 1.

### Example 2

This example was identical to Example 1, except that a holding time at 1200° C. was changed from 6 h to 12 h.

### Example 3

This example was identical to Example 1, except that holding for 6 h at 1200° C. was replaced with holding for 1 h at 1400° C.

### Example 4

This example was identical to Example 1, except that holding for 6 h at 1200° C. was replaced with holding for 6 h at 1400° C.

### Example 5

This example was identical to Example 1, except that holding for 6 h at 1200° C. was replaced with holding for 12 h at 1400° C.

### Example 6

This example was identical to Example 1, except that the additional element was changed from 1.0068 of calcium carbonate (CaCO₃, purity 99.99 wt. %) to 0.40551 g (equivalent to 0.0075 wt. % as magnesium element) of magnesium oxide (MgO, purity 99.99 wt. %).

### Example 7

This example was identical to Example 1, except that the additional element was changed from 1.0068 of calcium carbonate (CaCO₃, purity 99.99 wt. %) to 0.40551 g of magnesium oxide (MgO, purity 99.99 wt. %) and a holding time at 1200° C. was changed from 6 h to 12 h.

### Example 8

This example was identical to Example 1, except that the additional element was changed from 1.0068 of calcium carbonate (CaCO₃, purity 99.99 wt. %) to 0.40551 g (equivalent to 0.0075 wt. % as magnesium element) of magnesium oxide (MgO, purity 99.99 wt. %) and holding for 6 h at 1200° C. was replaced with holding for 1 h at 1400° C.

### Example 9

This example was identical to Example 1, except that the additional element was changed from 1.0068 of calcium carbonate (CaCO₃, purity 99.99 wt. %) to 0.40551 g (equivalent to 0.0075 wt. % as magnesium element) of magnesium oxide (MgO, purity 99.99 wt. %) and holding for 6 h at 1200° C. was replaced with holding for 6 h at 1400° C.

### Example 10

This example was identical to Example 1, except that the additional element was changed from 1.0068 of calcium carbonate (CaCO₃, purity 99.99 wt. %) to 0.40551 g (equivalent to 0.0075 wt. % as magnesium element) of magnesium oxide (MgO, purity 99.99 wt. %) and holding for 6 h at 1200° C. was replaced with holding for 12 h at 1400° C.

### Example 11

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal.

### Example 12

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal and a holding time at 1200° C. was changed from 6 h to 12 h.

### Example 13

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal and holding for 6 h at 1200° C. was replaced with holding for 1 h at 1400° C.

### Example 14

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal and holding for 6 h at 1200° C. was replaced with holding for 6 h at 1400° C.

### Example 15

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal and holding for 6 h at 1200° C. was replaced with holding for 12 h at 1400° C.

### Example 16

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal and 1.0068 g of calcium carbonate (CaCO₃, purity 99.99 wt. %) as the additional element was replaced with 1.5104 g (0.0279 wt. % as Ca element).

### Example 17

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal, 1.0068 g of calcium carbonate (CaCO₃, purity 99.99 wt. %) as the additional element was replaced with 1.5104 g, and a holding time at 1200° C. was changed from 6 h to 12 h.

### Example 18

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ)LuᵣCeₛSiO₅ (r=0.4, s=0.013) single crystal, 1.0068 g of calcium carbonate (CaCO₃, purity 99.99 wt. %) as the additional element was replaced with 1.5104 g, and holding for 6 h at 1200° C. was replaced with holding for 1 h at 1400° C.

### Example 19

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal, 1.0068 g of calcium carbonate (CaCO₃, purity 99.99 wt. %) as the additional element was replaced with 1.5104 g, and holding for 6 h at 1200° C. was replaced with holding for 6 h at 1400° C.

### Example 20

This example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal, 1.0068 g of calcium carbonate (CaCO₃, purity 99.99 wt. %) as the additional element was replaced with 1.5104 g, and holding for 6 h at 1200° C. was replaced with holding for 12 h at 1400° C.

### Example 21

This example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal.

### Example 22

This example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal and a holding time at 1200° C. was changed from 6 h to 12 h.

### Example 23

This example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal and holding for 6 h at 1200° C. was replaced with holding for 1 h at 1400° C.

### Example 24

This example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal and holding for 6 h at 1200° C. was replaced with holding for 6 h at 1400° C.

### Example 25

This example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal and holding for 6 h at 1200° C. was replaced with holding for 12 h at 1400° C.

### Comparative Example 1

This comparative example was identical to Example 1, except that calcium carbonate was not added.

### Comparative Example 2

This comparative example was identical to Example 1, except that calcium carbonate was not added and a holding time at 1200° C. was changed from 6 h to 12 h.

### Comparative Example 3

This comparative example was identical to Example 1, except that calcium carbonate was not added and holding for 6 h at 1200° C. was replaced with holding for 1 h at 1400° C.

### Comparative Example 4

This comparative example was identical to Example 1, except that calcium carbonate was not added and holding for 6 h at 1200° C. was replaced with holding for 6 h at 1400° C.

### Comparative Example 5

This comparative example was identical to Example 1, except that calcium carbonate was not added and holding for 6 h at 1200° C. was replaced with holding for 12 h at 1400° C.

### Comparative Example 6

This comparative example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal, and calcium carbonate was not added.

### Comparative Example 7

This comparative example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal, calcium carbonate was not added, and a holding time at 1200° C. was changed from 6 h to 12 h.

### Comparative Example 8

This comparative example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal, calcium carbonate was not added, and holding for 6 h at 1200° C. was replaced with holding for 1 h at 1400° C.

### Comparative Example 9

This comparative example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal, calcium carbonate was not added, and holding for 6 h at 1200° C. was replaced with holding for 6 h at 1400° C.

### Comparative Example 10

This comparative example was identical to Example 1, except that the Gd₂₋₍ᵣ₊ₛ₎LuᵣCeₛSiO₅ (r=0.4, s=0.02) single crystal was replaced with a Gd₂₋₍ᵣ₊ₛ₎LuᵣCeₛSiO₅ (r=0.4, s=0.013) single crystal, calcium carbonate was not added, and holding for 6 h at 1200° C. was replaced with holding for 12 h at 1400° C.

### Comparative Example 11

This comparative example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal, and calcium carbonate was not added.

### Comparative Example 12

This comparative example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal, calcium carbonate was not added, and a holding time at 1200° C. was changed from 6 h to 12 h.

### Comparative Example 13

This comparative example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal, calcium carbonate was not added, and holding for 6 h at 1200° C. was replaced with holding for 1 h at 1400° C.

### Comparative Example 14

This comparative example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal, calcium carbonate was not added, and holding for 6 h at 1200° C. was replaced with holding for 6 h at 1400° C.

### Comparative Example 15

This comparative example was identical to Example 1, except that the Gd₂₋₍ᵣ₊ₛ₎LuᵣCeₛSiO₅ (r=0.4, s=0.02) single crystal was replaced with a Y₂₋₍ᵣ₊ₛ₎LuᵣCeₛSiO₅ (r=0.4, s=0.02) single crystal, calcium carbonate was not added, and holding for 6 h at 1200° C. was replaced with holding for 12 h at 1400° C.

The light output and energy resolution of single crystals samples of Examples 2 to 25 and Comparative Examples 1 to 15 were measured by the same method as in Example 1. The results are shown in Tables 1 to 5.

TABLE 1

| | | Additional | | | | | | |
|---|---|---|---|---|---|---|---|---|
| | | element/ | | Heat treatment conditions | | | | |
| | Crystal | concentration | Growth | | Temperature | | Light | Energy |
| | composition | (wt. %) | atmosphere | Atmosphere | T (° C.) | Holding time (hr) | output (ch) | resolution (%) |
| Example 1 | Gd₂₋₍ᵣ₊ₛ₎LuᵣCeₛSiO₅ | Ca/0.0186 | N₂/O₂ (O₂: | N₂/O₂ (O₂: | 1200 | 6 | 689 | 9.5 |
| | (r = 0.4, | | 0.25 vol. %) | 0.25 vol. %) | | | 693 | 9.4 |
| Example 2 | s = 0.02) | | | | | 12 | 714 | 9.2 |
| | | | | | | | 713 | 9.3 |
| Example 3 | | | | | 1400 | 1 | 683 | 9.3 |
| | | | | | | | 676 | 9.4 |
| Example 4 | | | | | | 6 | 715 | 9.1 |
| | | | | | | | 709 | 8.8 |
| Example 5 | | | | | | 12 | 721 | 8.7 |
| | | | | | | | 723 | 8.6 |
| Example 6 | | Mg/0.0075 | | | 1200 | 6 | 657 | 9.7 |
| | | | | | | | 662 | 9.6 |
| Example 7 | | | | | | 12 | 668 | 9.3 |
| | | | | | | | 692 | 9.4 |
| Example 8 | | | | | 1400 | 1 | 657 | 9.5 |
| | | | | | | | 655 | 9.7 |
| Example 9 | | | | | | 6 | 678 | 9.3 |
| | | | | | | | 681 | 9.2 |
| Example | | | | | | 12 | 691 | 8.9 |
| 10 | | | | | | | 694 | 8.9 |

TABLE 2

| | | Additional | | Heat treatment conditions | | | | Energy |
|---|---|---|---|---|---|---|---|---|
| | Crystal | concentration | Growth | | Temperature | Holding | Light | resolution |
| | composition | (wt. %) | atmosphere | Atmosphere | T (° C.) | time (hr) | output (ch) | (%) |
| Comparative | Gd₂₋₍ᵣ₊ₛ₎LuᵣCeₛSiO₅ | None | N₂/O₂ (O₂: | N₂/O₂ (O₂: | 1200 | 6 | 570 | 10.1 |
| Example 1 | (r = 0.4, | | 0.25 vol. %) | 0.25 vol. %) | | | 569 | 10.4 |
| Comparative | s = 0.02) | | | | | 12 | 590 | 10.2 |
| Example 2 | | | | | | | 588 | 10.1 |
| Comparative | | | | | 1400 | 1 | 583 | 10.1 |
| Example 3 | | | | | | | 579 | 10.5 |
| Comparative | | | | | | 6 | 599 | 9.9 |
| Example 4 | | | | | | | 602 | 10.1 |
| Comparative | | | | | | 12 | 604 | 10.1 |
| Example 5 | | | | | | | 603 | 10.2 |

TABLE 3

| | | Additional | | | | | | |
|---|---|---|---|---|---|---|---|---|
| | | element/ | | Heat treatment conditions | | | | |
| | Crystal | concentration | Growth | | Temperature | Holding | Light | Energy |
| | composition | (wt. %) | atmosphere | Atmosphere | T (° C.) | time (hr) | output (ch) | resolution (%) |
| Example 11 | Gd₂₋₍ᵣ₊ₛ₎LuᵣCeₛSiO₅ | Ca/0.0186 | N₂/O₂ (O₂: | N₂/O₂ (O₂: | 1200 | 6 | 704 | 9.2 |
| | (r = 0.4, | | 0.25 vol. %) | 100 ppm or | | | 710 | 9.1 |
| Example 12 | s = 0.013) | | | less) | | 12 | 734 | 8.7 |
| | | | | | | | 743 | 8.5 |
| Example 13 | | | | | 1400 | 1 | 680 | 9.3 |
| | | | | | | | 694 | 9.2 |
| Example 14 | | | | | | 6 | 722 | 8.7 |
| | | | | | | | 725 | 8.7 |
| Example 15 | | | | | | 12 | 741 | 8.8 |
| | | | | | | | 738 | 8.5 |
| Example 16 | | Ca/0.0279 | | | 1200 | 6 | 672 | 9.4 |
| | | | | | | | 683 | 9.2 |
| Example 17 | | | | | | 12 | 720 | 8.6 |
| | | | | | | | 732 | 8.8 |
| Example 18 | | | | | 1400 | 1 | 699 | 9.4 |
| | | | | | | | 711 | 9.2 |
| Example 19 | | | | | | 6 | 712 | 8.6 |
| | | | | | | | 721 | 8.7 |
| Example 20 | | | | | | 12 | 722 | 8.5 |
| | | | | | | | 731 | 8.6 |

TABLE 4

| | | | | Heat treatment conditions | | | | |
|---|---|---|---|---|---|---|---|---|
| | | Additional element/ | | | | Holding | Light | Energy |
| | Crystal | concentration | Growth | | Temperature | time | output | resolution |
| | composition | (wt. %) | atmosphere | Atmosphere | T (° C.) | (hr) | (ch) | (%) |
| Comparative | Gd₂₋₍ᵣ₊ₛ₎LuᵣCeₛSiO₅ | None | N₂/O₂ (O₂: | N₂/O₂ (O₂: | 1200 | 6 | 590 | 10.3 |
| Example 6 | (r = 0.4, | | 0.25 vol. %) | 100 ppm or | | | 597 | 10.4 |
| Comparative | s = 0.013) | | | less) | | 12 | 620 | 10.1 |
| Example 7 | | | | | | | 625 | 9.9 |
| Comparative | | | | | 1400 | 1 | 601 | 9.8 |
| Example 8 | | | | | | | 604 | 10.1 |
| Comparative | | | | | | 6 | 632 | 9.9 |
| Example 9 | | | | | | | 624 | 9.8 |
| Comparative | | | | | | 12 | 633 | 9.9 |
| Example 10 | | | | | | | 630 | 10.1 |

TABLE 5

| | | Additional | | | | | | |
|---|---|---|---|---|---|---|---|---|
| | | element/ | | Heat treatment conditions | | | | |
| | Crystal | concentration | Growth | | Temperature | Holding | Light | Energy |
| | composition | (wt. %) | atmosphere | Atmosphere | T (° C.) | time (hr) | output (ch) | resolution (%) |
| Example 21 | Y₂₋₍ᵣ₊ₛ₎LuᵣCeₛSiO₅ | Ca/0.0186 | N₂/O₂ (O₂: | N₂/O₂ (O₂: | 1200 | 6 | 653 | 9.6 |
| | (r = 0.4, | | 0.25 vol. %) | 100 ppm or | | | 658 | 9.4 |
| Example 22 | s = 0.02) | | | less) | | 12 | 679 | 9.2 |
| | | | | | | | 682 | 9.1 |
| Example 23 | | | | | 1400 | 1 | 667 | 9.3 |
| | | | | | | | 668 | 9.3 |
| Example 24 | | | | | | 6 | 680 | 9.2 |
| | | | | | | | 679 | 9.1 |
| Example 25 | | | | | | 12 | 685 | 8.9 |
| | | | | | | | 684 | 8.8 |
| Comparative | | None | | | 1200 | 6 | 550 | 10.8 |
| Example 11 | | | | | | | 554 | 10.9 |
| Comparative | | | | | | 12 | 571 | 10.5 |
| Example 12 | | | | | | | 569 | 10.6 |
| Comparative | | | | | 1400 | 1 | 565 | 10.6 |
| Example 13 | | | | | | | 559 | 10.7 |
| Comparative | | | | | | 6 | 572 | 10.4 |
| Example 14 | | | | | | | 568 | 10.4 |
| Comparative | | | | | | 12 | 576 | 10.3 |
| Example 15 | | | | | | | 574 | 10.4 |

As shown in Tables, the light output and energy resolution in the Examples 1 to 25 (additional elements are present) were higher than those in Comparative Examples 1 to 15 (no additional elements). This is because conducting heat treatment in a nitrogen atmosphere with a low concentration of oxygen further enhanced the reduction reaction of tetravalent Ce into trivalent Ce in the single crystals containing Ca or Mg, eliminated the coloration of the crystals, and improved scintillator characteristics.

As for the heat treatment conditions, holding for 12 h at 12000 or for 6 h at 1400° C. appears to improve the scintillator characteristics for all the compositions as compared with holding for 6 h at 1200° C. or for 1 h at 1400° C. If the heating temperature is decreased the holding time apparently has to be extended in order to obtain the same characteristic for the same composition.

What is claimed is:

1. A method for heat treating a single crystal, comprising a step of heating a single crystal of a cerium-activated orthosilicate compound, represented by general formula (1) or (2) below, that comprises 0.00005 to 0.1 wt. % of an element of Group 2 of the periodic table at a temperature T₁ (units: ° C.) satisfying a condition represented by formula (3) below in an atmosphere with a low concentration of oxygen:
Y_{2-(x+y)}LnₓCe_{y}SiO₅ (1)
wherein Ln denotes at least one element selected from a group consisting of elements belonging to rare earth elements, x is a numerical value of 0 to 1, and y is a numerical value of more than 0 and equal to or less than 0.2;
Gd_{2-(z+w)}Ln_{z}Ce_{w}SiO₅ (2)
wherein Ln denotes at least one element selected from a group consisting of elements belonging to rare earth elements, z is a numerical value of more than 0 and equal to or less than 1, and w is a numerical value of more than 0 and equal to or less than 0.2;
800≦T₁<(Tₘ₁−550) (3)
wherein Tₘ₁ (units: ° C.) denotes a melting point of said single crystal.

2. A method for heat treating a single crystal, comprising a step of heating a single crystal of a cerium-activated orthosilicate compound, represented by general formula (4) below, that comprises 0.00005 to 0.1 wt. % of an element of Group 2 of the periodic table at a temperature T₂ (units: ° C.) satisfying a condition represented by formula (5) below in an atmosphere with a low concentration of oxygen:
Gd_{2-(p+q)}LnₚCe_{q}SiO₅ (4)
wherein Ln denotes at least one element selected from a group consisting of Dy, Ho, Er, Tm, Yb, Lu, Y, and Sc, which are rare earth elements with an ion radius less than that of Th, p is a numerical value of more than 0 and equal to or less than 1, and q is a numerical value of more than 0 and equal to or less than 0.2;
800≦T₂<(Tₘ₂−550) (5)
wherein Tₘ₂ (units: ° C.) denotes a melting point of said single crystal.

3. A method for heat treating a single crystal, comprising a step of heating a single crystal of a cerium-activated orthosilicate compound, represented by general formula (6) below, that comprises 0.00005 to 0.1 wt. % of an element of Group 2 of the periodic table at a temperature T₃ (units: ° C.) satisfying a condition represented by formula (7) below in an atmosphere with a low concentration of oxygen:
Gd₂₋₍ᵣ₊ₛ₎LuᵣCeₛSiO₅ (6)
wherein Tₘ₃ is a numerical value of more than 0 and equal to or less than 1, and s is a numerical value of more than 0 and equal to or less than 0.2;
800≦T₃<(Tₘ₃−550) (7)
wherein Tₘ₃ (units: ° C.) denotes a melting point of said single crystal.

4. The method for heat treating a single crystal according to claim 1, wherein a concentration of oxygen in said atmosphere with a low concentration of oxygen is less than 0.2 vol. % and the balance is an inactive gas.

5. The method for heat treating a single crystal according to claim 2, wherein a concentration of oxygen in said atmosphere with a low concentration of oxygen is less than 0.2 vol. % and the balance is an inactive gas.

6. The method for heat treating a single crystal according to claim 3, wherein a concentration of oxygen in said atmosphere with a low concentration of oxygen is less than 0.2 vol. % and the balance is an inactive gas.

7. The method for heat treating a single crystal according to claim 1, wherein a concentration of hydrogen in said atmosphere with a low concentration of oxygen is 0.5 vol. % or more.

8. The method for heat treating a single crystal according to claim 2, wherein a concentration of hydrogen in said atmosphere with a low concentration of oxygen is 0.5 vol. % or more.

9. The method for heat treating a single crystal according to claim 3, wherein a concentration of hydrogen in said atmosphere with a low concentration of oxygen is 0.5 vol. % or more.

10. The method for heat treating a single crystal according to claim 4, wherein a concentration of hydrogen in said atmosphere with a low concentration of oxygen is 0.5 vol. % or more.

11. The method for heat treating a single crystal according to claim 5, wherein a concentration of hydrogen in said atmosphere with a low concentration of oxygen is 0.5 vol. % or more.

12. The method for heat treating a single crystal according to claim 6, wherein a concentration of hydrogen in said atmosphere with a low concentration of oxygen is 0.5 vol. % or more.

13. The method for heat treating a single crystal according to claim 1, wherein said element of Group 2 of the periodic table is at least one element selected from a group consisting of Be, Mg, Ca, and Sr.

14. The method for heat treating a single crystal according to claim 2, wherein said element of Group 2 of the periodic table is at least one element selected from a group consisting of Be, Mg, Ca, and Sr.

15. The method for heat treating a single crystal according to claim 3, wherein said element of Group 2 of the periodic table is at least one element selected from a group consisting of Be, Mg, Ca, and Sr.

16. The method for heat treating a single crystal according to claim 1, wherein said single crystal is a single crystal that is grown or cooled in an atmosphere comprising oxygen or a single crystal that is heated in an atmosphere comprising oxygen before the heat treatment step.

17. The method for heat treating a single crystal according to claim 2, wherein said single crystal is a single crystal that is grown or cooled in an atmosphere comprising oxygen or a single crystal that is heated in an atmosphere comprising oxygen before the heat treatment step.

18. The method for heat treating a single crystal according to claim 3, wherein said single crystal is a single crystal that was grown or cooled in an atmosphere comprising oxygen or a single crystal that is heated in an atmosphere comprising oxygen before the heat treatment step.
